(19) United States
(12) Patent Application Publication
(10) Pub. No.: US 2006/0144520 A1
(43) Pub. Date: Jul. 6, 2006

(54) Viewing window cleaning apparatus

(75) Inventor: Steven T. Fink, Mesa, AZ (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/522,189

(22) PCT Filed: Sep. 22, 2003
(86) PCT No.: PCT/US03/26302

§ 371 Date: Jan. 24, 2005

Related U.S. Application Data
(60) Provisional application No. 60/411,760, filed on Sep. 19, 2002.

(51) Int. Cl. B08B 6/00; C23F 1/00; C23C 16/00

(52) U.S. Cl. 156/345.48; 134/1.1; 118/723 I

(57) ABSTRACT

A viewing port for a processing chamber is provided that includes a viewing window cleaning apparatus, a viewing window, and a mounting, where the viewing window cleaning apparatus is coupled to the mounting and disposed between the viewing window and the process chamber, and is configured to form a cleaning plasma in a cleaning plasma region of the mounting. In addition, the mounting can be configured to reduce a number of by-products from a process chamber on the viewing window by preventing them from propagating to the window.

### RELATED APPLICATIONS

This application is related to and claims priority to U.S. Provisional Application Ser. No. 60/411,760, filed Sep. 19, 2002, which is related to pending International Application No. PCT/US02/22080, filed on Mar. 25, 2002, which claims priority to U.S. application Ser. No. 60/277,965, entitled “Inductively coupled high-density plasma source”, filed on Mar. 23, 2001 and U.S. application Ser. No. 60/277,966, entitled “Inductively coupled high-density plasma source”, filed on Mar. 23, 2001. The entire contents of all of those applications are herein incorporated by reference.

### BACKGROUND OF THE INVENTION

1. Field of the Invention

This invention is directed to an apparatus for maintaining a cleanliness of a viewing window by (1) removing accumulated by-products from the viewing window, (2) preventing accumulation of by-products on the viewing window, or (3) both.

2. Discussion of the Background

In the manufacturing and production of semiconductor devices, the use of plasma processing is a commonly accepted practice to facilitate the many etch and deposition steps required during the evolution of the device. For example, silicon wafers, providing a base substrate for fabricating silicon-based semiconductor devices, are loaded into the plasma processing chambers and exposed in various steps to a processing plasma, wherein a material is either removed from (etch) or added to (deposition) selective regions of the substrate.

Optical plasma diagnostics are frequently used in plasma processing for plasma process characterization, process endpoint detection, etc. Such diagnostics require optical access to the plasma processing region via a window that is sufficiently transparent to the optical wavelengths of interest, and that provides a reliable vacuum seal. Most optical diagnostic methods require acquisition of entire spectra using a scanning monochromator, spectrograph, or similar device. In these cases, it is important that the window maintain high transparency over entire spectral regions of interest.

One of the most frequently encountered problems in optical diagnostics of plasma processes is film deposition on the optical diagnostics window, or observation viewing port. The observation viewing port is in contact with the processing plasma, on one side, and in typical plasma etch and deposition chemistries, local plasma conditions at the viewing port cause the formation of a film consisting of adsorbed chemical species present in the processing plasma. During wafer processing, the film grows on the viewing port leading to gradual deterioration of acquired optical signals. This deterioration leads to non-repeatability of optical signal measurements made under the same conditions, which can affect processing tool control systems that base their action on input from optical diagnostic sensors.

In summary, regardless of the specific optical method used, observation viewing ports in the chamber wall, such as the viewing port illustrated in FIG. 1, must remain relatively clean. If not, data gathered by observation or experimentation could be inaccurate. (FIG. 1 illustrates one such viewing window 400a attached to a plasma chamber 200a by standard ISO-KF hardware 300a.)

Therefore, it is necessary to clean the viewing port of accumulated or deposited materials. Previously, this meant removing the viewing port and manually cleaning the glass. However, because of the time and labor necessary to perform this task, cleaning the viewing ports in this manner was a costly problem.

### SUMMARY OF THE INVENTION

The present invention provides an apparatus and a method for cleaning a viewing window, preferably of a process chamber, without the added costs and labor of removing the viewing window, so data obtained by observing the process chamber is accurate. Thus, the present invention describes an apparatus and a method for cleaning windows without the need for removal of the windows.

According to a first embodiment of the invention, by-products (or other materials) are removed from a viewing window of a process chamber by physical or chemical etching. Preferably, a secondary plasma source is mounted adjacent to the viewing window. The plasma generated by the secondary plasma source etches the by-products that have accumulated on the viewing window.

According to a second embodiment, the cleanliness of the viewing window, preferably mounted to a process chamber, is maintained by reducing an amount of by-product that accumulates on the viewing window in the first place.

Preferably, the viewing window is supported in a predetermined position or location relative to the process chamber so that the number of by-products propagating to the viewing window is substantially reduced.

Additionally, in yet another alternate embodiment, a plurality of magnets reduces the accumulation of by-products from the process chamber on the viewing window. The magnets generate a magnetic field that reduces the amount of by-products of the process chamber that reach the viewing window. In a further alternate embodiment, a gas injection system reduces the accumulation of by-products from the process chamber on the viewing window by pressurizing a section of the process chamber near the viewing window.

Combinations of any of the above noted features can be used to either remove by-products from the viewing window or reduce by-products accumulation on the viewing window.

### BRIEF DESCRIPTION OF THE DRAWINGS

A more complete appreciation of the invention and many of the attendant advantages thereof will become readily apparent with reference to the following detailed description particularly when considered in conjunction with the accompanying drawings, in which:

FIG. 1 is a view of a known viewing window in which the viewing window is mounted directly to a process chamber;

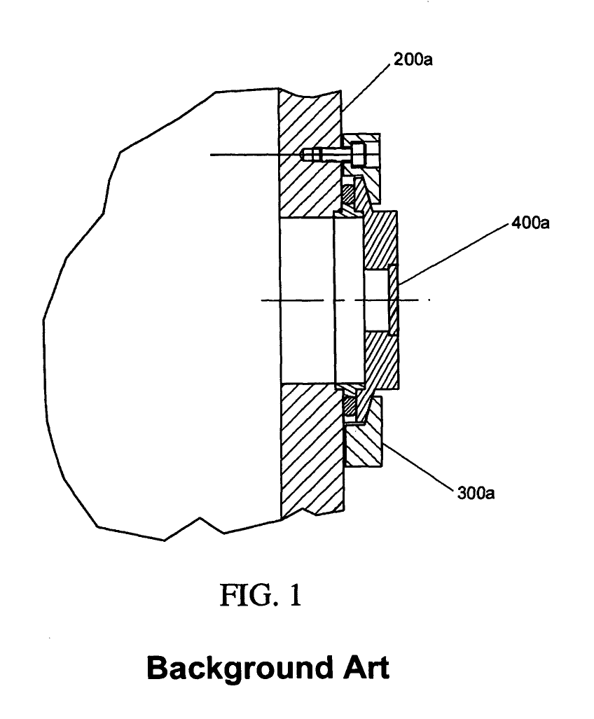

FIG. 2 is a view of a viewing window cleaning apparatus that is mounted in close proximity to a viewing window separated from the process chamber by a short distance;

FIG. 3A is an schematic view of the plasma source of FIG. 2;

FIG. 3B is an expanded view of the match assembly and a top portion of the plasma resonator coil;

FIG. 4 is a side view of a viewing window mounted at a predetermined inclination relative to the process chamber;

FIG. 5A is a side view of a plurality of magnets arranged so as to generate a magnetic field preventing by-products from propagating to the viewing window;

FIG. 5B is a cross-sectional view of a plurality of magnets arranged so as to generate a magnetic field preventing by-products from propagating to the viewing window;

FIG. 6 is a side view of a gas injection system employed to pressurize a section of the extension separating the viewing window from the process chamber; and

FIG. 7 is a view of an exemplary combination of the above noted features in relation to each other.

### DETAILED DESCRIPTION OF THE INVENTION

Referring now to the drawings, wherein like reference numerals designate identical or corresponding parts throughout the several views, a viewing window cleaning apparatus can be built with an apparatus (1) for removing by-products from a process chamber that have accumulated on a viewing window, (2) for reducing the number of particles which propagate to the viewing window, or (3) both.

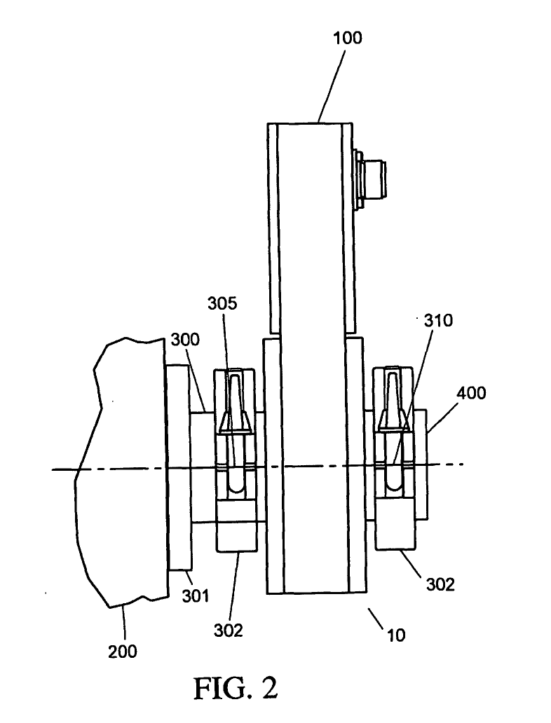

The present invention provides an apparatus and a method for addressing the deficiencies of known plasma chamber viewing windows. According to the invention, with reference to FIG. 2, the process chamber 200 is a large chamber in which plasma can be created. The process chamber 200 is equipped with a viewing port 10 that comprises: a viewing window 400 to permit optical access to the process chamber; a mounting 300 to couple the viewing port to the process chamber; and a viewing window cleaning apparatus 100. In addition, mounting 300 separates a viewing window 400 from the process chamber 200. For example, the mounting 300 can be constructed to be compatible with standard ISO-KF hardware 301. The mounting can also comprise connection members 302 which secure various sections of the mounting to each other and which may extend the mounting to the desired distance. The viewing window 400 and mounting 300 provide a view into the process chamber 200 that enables a process in the chamber 200 to be monitored.

According to a first embodiment, by-products of the process chamber 200 are removed from the viewing window 400. A viewing window cleaning apparatus 100 is preferably situated on the mounting 300 exterior to a process chamber 200 and adjacent a viewing window 400. First interface section 305 is located at the connection point of the mounting 300 and the viewing window cleaning system 100 and faces the process chamber 200. Second interface section 310 is located opposite the first interface 305 and faces the viewing window 400. A plasma generated by the viewing window cleaning system 100 removes by-products from the viewing window 400 that have migrated from the process chamber 200. To achieve removal, interface section 310 brings the viewing window 400 close enough such that the plasma generated by the viewing window cleaning system 100 removes by-products on the viewing window. The process of removal can be a physical or chemical etching process, or a combination of physical and chemical etching processes.

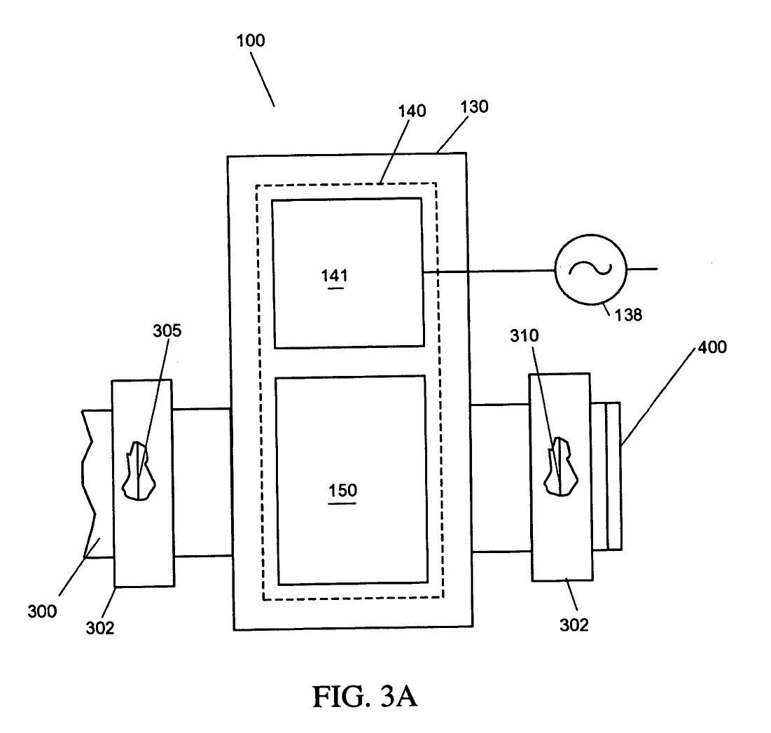

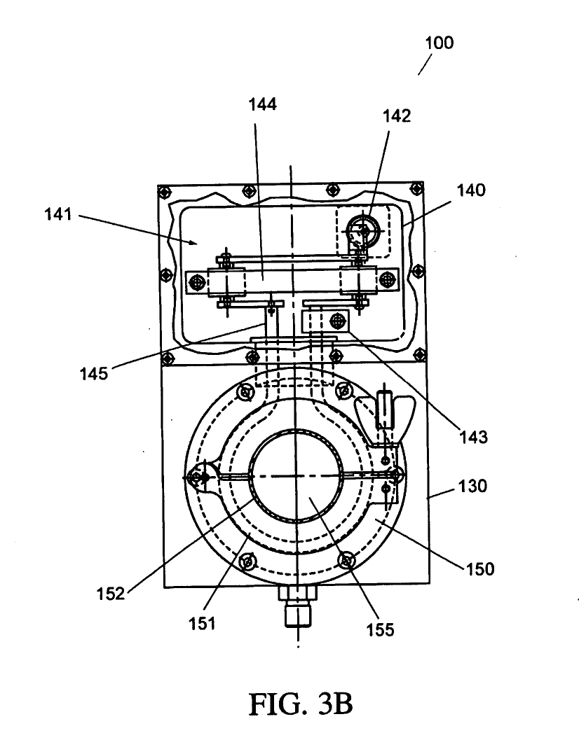

Referring to FIGS. 3A, and 3B, the viewing window cleaning apparatus 100 can include at least two components: the outer housing 130 and the plasma source 140. The housing 130 can provide structural support for the plasma source 140, as well as provide shielding of RF energy utilized to energize the plasma source 140.

The housing also includes connection members 302. The connection members 302 provide a vacuum-tight connection with the mounting member 300, provide support for the viewing window cleaning apparatus 100 on the mounting 300, and allow for necessary maintenance of the various parts.

The plasma source 140 further includes an impedance match assembly 141, and a plasma generator 150. The impedance match assembly 141 maximizes the transfer of power from an RF source 138 to the cleaning plasma in a cleaning plasma region 155 through plasma generator 150 by providing an impedance match to counter the inherent reactive impedance component inherent within the plasma generating system. Typically, the adjustable components, such as vacuum variable capacitors, housed within the impedance match assembly 141 are operated via an automatic control system (not shown) provided with measurements of the forward and reflected RF power. The design and use, both automatically and manually, of impedance match networks for plasma generation are well known to those skilled in the art of RF systems and plasma source design. In accordance with this invention, known match assembly components have been adapted to perform in the small space available in the viewing window cleaning apparatus 100. For example, details of the design of plasma source 140 are provided for a compact inductively coupled plasma source in pending International Application No. PCT/US02/22080, filed on Mar. 25, 2002, which claims priority to U.S. application Ser. No. 60/277,965, entitled “Inductively coupled high-density plasma source”, filed on Mar. 23, 2001 and U.S. application Ser. No. 60/277,966, entitled “Inductively coupled high-density plasma source”, filed on Mar. 23, 2001, which are incorporated herein by reference in their entirety.

In particular, for example, the impedance match assembly 141 can include a first variable capacitor 142 comprising an input end coupled to an output of the RF source 138 and an output end coupled to a first end 143 of an inductive coil 151, a second variable capacitor 144 comprising a first end coupled to the first end of the inductive coil 151 and a second end coupled to a second end 145 of the inductive coil 151, and the second end of the inductive coil 151 and second end of variable capacitor 144 are coupled to ground. For example, variable capacitor 142 and variable capacitors 144 can comprise one or more fixed capacitors.

The plasma generator 150 can include the inductive coil 151 coupled to the impedance match assembly 141 and positioned to surround a process tube 152. Alternately, a different impedance match assembly configuration can be employed. An ionizable gas can be supplied to the cleaning plasma region 155 from the gas injection system utilized for forming the processing plasma in process chamber 200 either during wafer processing or during times between wafer processing. Alternatively, a secondary gas injection system coupled either to the viewing window cleaning apparatus 100 or the mounting member 300 is utilized to locally inject an ionizable and/or dissociative gas into the cleaning plasma region 155. For example, when the viewing window cleaning (etching) process is desirably a physical process, a heavy inert gas such as argon, krypton, xenon, etc. can be used. Conversely, when the viewing window cleaning (etching) process is desirably a chemical process, a reactive gas such as NF3, CF₄, SF₆, C₂F₆, CCl₄, C₂Cl₆ can be supplied. When the viewing window cleaning (etching) process comprises both physical and chemical processes, a combination of heavy and reactive gases can be used.

Alternately, vacuum sealable gas injection holes (not shown) can be arranged along the process tube through which injected gas migrates to the plasma generating area. When the viewing window cleaning apparatus 100 is activated, RF power is coupled from the RF source 138 through the impedance match assembly 141 to the cleaning plasma region 155 using inductive coil 151. The associated RF fields, in the presence of the injected gas, generates the plasma that is used to clean the viewing window.

Preferably, exhaust gas is either pumped out of the cleaning plasma region and into the process chamber (not shown) or pumped directly out of the plasma source (not shown). When the exhaust gas is evacuated through the process chamber, the process chamber pumping system, which is already in place, can be used. When the exhaust gas is evacuated directly from the cleaning plasma region, either a secondary pumping system (not shown) is installed, or a secondary vacuum line (not shown) is installed to evacuate cleaning gases directly to the inlet of the process chamber pumping system without entering the process chamber. For example, in the case where the vacuum pumping system accesses the process chamber 200 from the side, the mounting 300 can be positioned on the process chamber 200 substantially proximate the pumping duct connecting the process chamber 200 to the inlet of the pumping system, and a vacuum line can be configured to couple the interior of the mounting 300 directly to the pumping duct, hence, bypassing the interior of the process chamber 200.

To further insure that exhaust gases are efficiently pumped into the process chamber during exhaustion of the viewing window cleaning apparatus 100, a gate valve (not shown) separating the plasma source from the process chamber may also be employed. Such a valve would ensure that exhaust gases were pumped out of the plasma source and the mounting into the process chamber without allowing exhaust from the process chamber into the mounting.

In a second embodiment, an amount of by-product from the process chamber that diffuses to the viewing window is reduced, while further implementing the viewing window cleaning apparatus above. The reduction of transport is accomplished by the use of various features as noted below. These features include, but are not limited to, any one or a combination of positioning the viewing window relative to the process chamber where an amount of by-product reaching the viewing window will be decreased, using magnets to reduce cross-field electron transport, and using pressurization of the mounting 300 to establish an adverse pressure gradient for material entering from the process chamber.

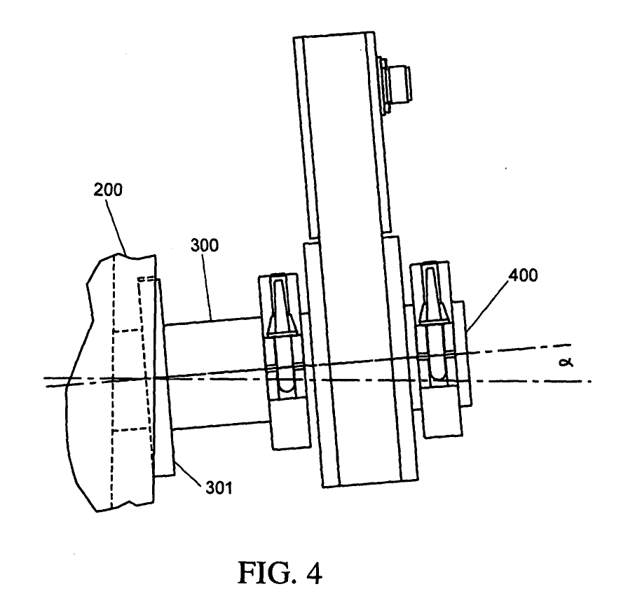

A first feature of the second embodiment is described with reference to FIG. 4. A viewing window 400 is mounted to a process chamber 200 by a mounting 300 at a pre-determined location on the process chamber. For example, the location can be determined on the basis of experimental data illustrating the location at which the transport of reaction by-products through the mounting is reduced. In addition, the viewing window cleaning apparatus 100 can be placed far enough from the process chamber that the amount of reaction by-products accumulating on the viewing window 400 is substantially reduced. Furthermore, the angle α, shown in FIG. 4, can be selected on the basis of experimental data illustrating the reduction of reaction by-product transport to the viewing window 400 by avoiding a direct line-of-sight between the viewing window 400 and the process chamber 200.

Nonetheless, angle α must not be so large as to prevent any clear-line-of sight from the viewing window to the area inside the process chamber at which measurements of the plasma condition are made.

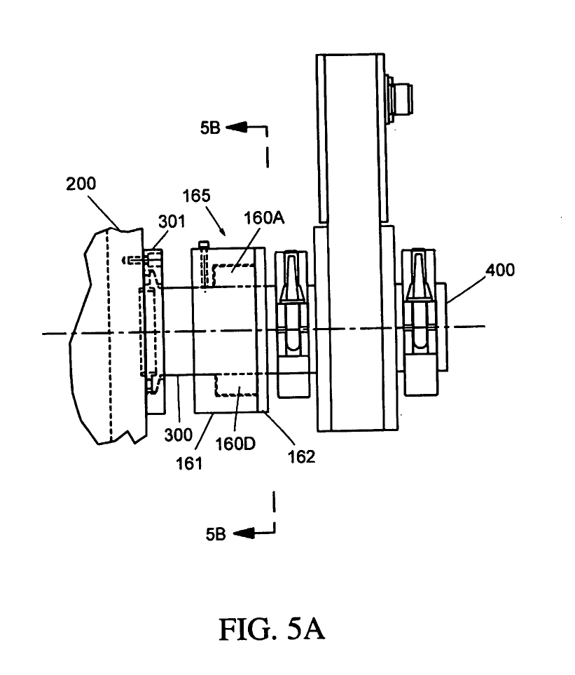

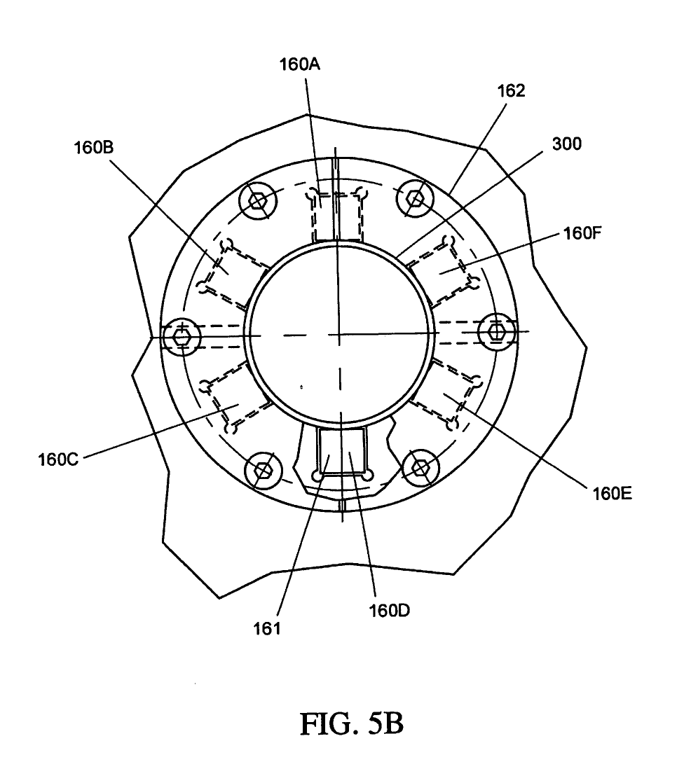

In addition to the features of FIG. 4, the mounting 300 can also be modified to include magnets as shown in FIGS. 5A and 5B. In FIGS. 5A and SB, a plurality of magnets 160A-160G is arranged so as to generate a magnetic field preventing cross-field electron transport between the plasma chamber 200 and the viewing window 400. Preferably, the magnets 160A-160G are arranged on the inner surface of the mounting 300. Consequently, they generate a magnetic field that extends substantially across the mounting 300, and they create a field strength sufficient to prevent the cross-field transport of electrons generated either by the processing plasma in process chamber 200 or the cleaning plasma in the viewing window cleaning apparatus 100. For example, the magnetic field strength is desirably at least 200 Gauss. The reduction of cross-field electron transport can provide a number of benefits including: isolation of the processing plasma from the cleaning plasma, isolation of the processing chemistry from the cleaning chemistry. Such magnets can be either permanent magnets or electromagnets, which can be controlled as needed (i.e., the magnetic field strength can be varied by controlling the signal level to an electromagnet).

The polarity of the magnets 160A-160G can be arranged to form a cusp field (i.e. the polarity of each magnet 160A-160G is the same; for example, north pole directed inward). Alternately, the polarity of adjacent magnets can be alternated. Alternately, the polarity of at least one magnet is different from the remaining magnets.

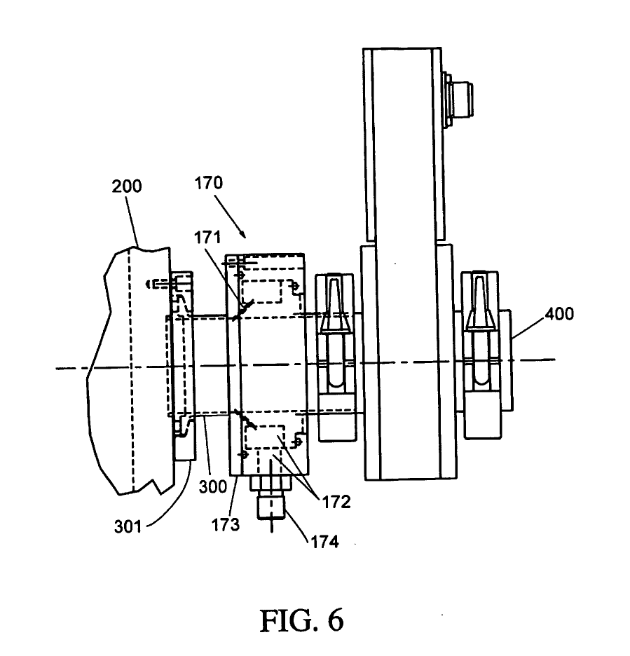

With reference to FIG. 6, a gas injection system 170 is installed internal to the mounting 300 so as to generate a pressure inside the mounting 300 reducing the amount of reaction by-products entering the mounting 300 that diffuse to the viewing window. A conduit 172 couples a gas supply system (not shown) to an inlet 171 or array of inlets on the mounting 300. The gas supply system (not shown) can be coupled to the gas injection system 170 via a connector 174. The connector 174 can, for example, be a VCR fitting or a Swagelock fitting. The gas supply system (not shown) provides a gas, such as an inert gas (i.e. Noble gases, nitrogen, etc.) through the conduit 172 into the mounting 300 through the inlet 171. As a pressure gradient is established inside the mounting 300 the amount of reaction by-products forming on the viewing window 400 is substantially reduced.

Alternately, a flow restrictor device within the mounting 300 can be utilized to facilitate the formation of a pressure gradient at a lower gas flow rate. Alternately, a reactive gas is injected through the gas injection system during a window cleaning process. Alternately, the gas is injected and directed to impinges on the viewing window surface. Alternately the flow of gas directed to impinge on the viewing window is pulsed.

In accordance with this invention, any one of the above noted features can be simultaneously combined in various combinations with any of the others. For example, the viewing window cleaning apparatus can be mounted between the viewing window and the plurality of magnets. Thus, the combination of the plurality of magnets and the viewing window apparatus can result in a significantly greater degree of reduction in the amount of reaction by-products accumulating on the viewing window. Similarly, the plurality of magnets, the gas injection system, and the viewing window cleaning system can all be installed on the mounting to affect a still greater degree of reduction.

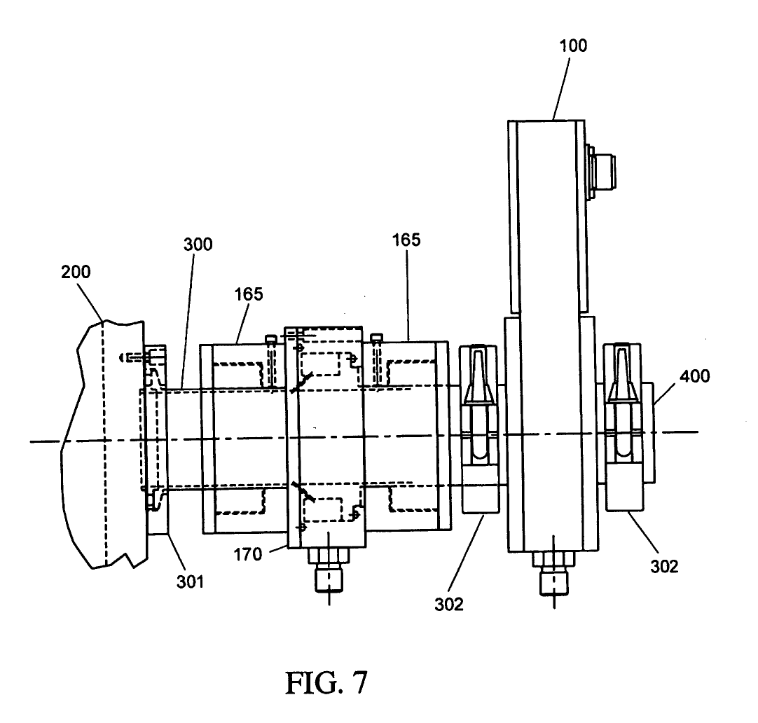

Particularly, with reference to FIG. 7, the viewing window cleaning apparatus 100, the positioning of the viewing window 400, the plurality of magnets 160A-160G, and the gas injection system 170 can all be combined at once. As shown in FIG. 7, the mounting 300 can be used to position the viewing window 400 at a particular location on the process chamber. A viewing window cleaning apparatus 100 is attached to the end of the mounting 300 near the viewing window 400 in position to physically etch or chemically etch by-products on the viewing window 400. Two sets of a plurality of magnets 160A-160G are arranged parallel to one another within the mounting. The gas injection system 170 pressurizes the mounting 300 further reducing the number of reaction by-products reaching the viewing window.

This invention may also be specified as a viewing window cleaning apparatus comprising a viewing window, a means for reducing a number of by-products from a process chamber on the viewing window, and a connection member configured to couple the reducing means to the process chamber.

This invention may also be specified as a method for cleaning a viewing window comprising the steps of positioning a wafer inside the process chamber, generating a plasma inside the process chamber, and reducing a number of by-products from the process chamber on a viewing window coupled to the process chamber without de-coupling the viewing window from the process chamber.

Numerous modifications and variations of the present invention are possible in light of the above teachings. It is therefore to be understood that, within the scope of the appended claims, the invention may be practiced otherwise than as specifically described herein.

1. A viewing port for a process chamber, comprising:
a viewing window to permit optical access to said process chamber;
a mounting to couple said viewing window to said process chamber; and
a viewing window cleaning apparatus coupled to said mounting and disposed between said viewing window and said process chamber, and configured to form a cleaning plasma in a cleaning plasma region of said mounting.

2. The viewing port as recited in claim 1, wherein said viewing window cleaning apparatus comprises a RF source and a plasma source.

3. The viewing port as recited in claim 2, wherein said viewing window cleaning apparatus further comprises an impedance match assembly and a plasma generator.

4. The viewing port as recited in claim 3, wherein said plasma generator comprises an inductive coil.

5. The mounting as recited in claim 1, further comprising at least one array of magnets coupled to said mounting.

6. The mounting as claimed in claim 5, wherein at least one of said magnets of the array comprises a permanent magnet.

7. The mounting as claimed in claim 7, wherein at least one of said magnets of the array comprises an electromagnet.

8. The mounting as recited in claim 1, further comprising a gas injection system coupled to said cleaning plasma region.

9. The mounting as recited in claim 8, wherein said cleaning plasma etches by-products deposited on said viewing window through physical etching.

10. The mounting as recited in claim 9, wherein said gas injection system provides at least one of argon, krypton, and xenon.

11. The mounting as recited in claim 8, wherein said cleaning plasma etches by-products deposited on said viewing window through chemical etching.

12. The mounting as recited in claim 11, wherein said gas injection system provides at least one of NF₃, CF₄, SF₆, C₂F₆, CCl₄, and C₂Cl₆.

13. The mounting as recited in claim 8, wherein said cleaning plasma etches by-products deposited on said viewing window through physical and chemical etching.

14. The mounting as recited in claim 13, wherein said gas injection system provides at least one of argon, krypton, xenon and at least one of NF₃, CF₃, SF₆, C₂F₉, CCl₄, and C₂Cl₆.

15. The mounting as recited in claim 1, comprising a viewing window supporting section configured to position said viewing window at a predetermined position relative to a position of the process chamber.

16. The mounting as recited in claim 15, wherein the predetermined position is selected so that a substantial amount of by-products do not travel to said viewing window.

17. The mounting port as recited in claim 8, wherein said gas injection system is configured to flow a gas into the cleaning plasma region so that a pressure is generated in the cleaning plasma region, the pressure substantially opposing a propagating direction of by-products.

18. The mounting as recited in claim 8, further comprising at least one array of magnets coupled to said mounting.

19. The mounting as claimed in claim 18, wherein at least one of said magnets of the array comprises a permanent magnet.

20. The mounting as claimed in claim 18, wherein at least one of said magnets of the array comprises an electromagnet.

21. An improved process chamber, the improvement comprising a viewing port coupled to said process chamber, wherein said viewing port comprises:
a viewing window to permit optical access to said process chamber;
a mounting to couple said viewing window to said process chamber; and
a viewing window cleaning apparatus coupled to said mounting and disposed between said viewing window and said process chamber, and configured to form a cleaning plasma in a cleaning plasma region of said mounting.

22. The improved process chamber as recited in claim 21, wherein said mounting further comprises a gas injection system coupled to said cleaning plasma region.

23. The improved process chamber as recited in claim 21, wherein said viewing window cleaning apparatus comprises a RF source.

24. The improved process chamber as recited in claim 21, wherein said viewing window cleaning apparatus comprises a plasma generator.

25. The improved process chamber as recited in claim 21, wherein said mounting further comprises at least one array of magnets coupled to said mounting.

26. The improved process chamber as claimed in claim 25, wherein at least one of said magnets of the array comprises a permanent magnet.

27. The improved process chamber as claimed in claim 25, wherein at least one of said magnets of the array comprises an electromagnet.

28. A method of cleaning a viewing window for a process chamber, said method comprising:
providing a viewing window cleaning apparatus disposed between said viewing window and said process chamber; wherein said viewing window cleaning apparatus is configured to form a cleaning plasma; and
forming said cleaning plasma in the region between said viewing window and said process chamber to facilitate cleaning of said viewing window.

29. The method as recited in claim 28, wherein the method further comprises generating a magnetic field to prevent cross-field electron transport between said plasma chamber and said viewing window.

30. The method as recited in claim 28, wherein the method further comprises providing a gas so that a pressure is generated in the region between said viewing window and said process chamber, the pressure substantially opposing a propagating direction of by-products from said process chamber.

31. The method as recited in claim 28, wherein the method further comprises positioning said viewing window at a predetermined position relative to a position of the process chamber, wherein the predetermined position is selected so that a substantial amount of by-products do not travel to said viewing window.

32. The method as recited in claim 28, wherein said cleaning plasma is formed using a RF source and a plasma generator.

33. The method as recited in claim 28, wherein said cleaning plasma etches by-products deposited on said viewing window using at least one of argon, krypton, xenon, NF₃, CF₄, SF₆, C₂F₆, CCl₄, and C₂Cl₆.
